(19) United States
(12) Patent Application Publication
(10) Pub. No.: US 2006/0141711 A1
(43) Pub. Date: Jun. 29, 2006

(54) Method of manufacturing flash memory device

(75) Inventor: Cha Deok Dong, Kyeongki-Do (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Kyoungki-do (KR)

(21) Appl. No.: 11/131,092

(22) Filed: May 17, 2005

(30) Foreign Application Priority Data
Dec. 24, 2004 (KR) 2004-111878

(51) Int. Cl. H01L 21/336

(52) U.S. Cl. 438/264

(57) ABSTRACT

The present invention relates to a method of manufacturing flash memory devices. According to the present invention, an inter-gate insulating film formed between a floating gate and a control gate is formed to have an NONON structure, thus removing the interface of polysilicon and an oxide film. It is thus possible to prevent a thickness of an inter-gate insulating film from increasing due to a subsequent oxidization process. Furthermore, the thickness of the inter-gate insulating film can be kept uniform regardless of the shape of a cell. It is thus possible to make uniform the operating speed among cells and also to reduce the slow program fail rate.

### BACKGROUND

1. Field of the Invention

The present invention relates to a method of manufacturing a flash memory device, and more specifically, to a method of manufacturing a flash memory device, wherein a thickness of an inter-gate insulating film formed between a floating gate and a control gate can be formed to be uniform.

2. Discussion of Related Art

In flash memory devices, in the case where an ONO (SiO₂—Si₃H₄—SiO₂) film is used as an inter-gate insulating film formed between a floating gate and a control gate, polysilicon films of the floating gate and the control gate are oxidized due to oxygen diffusion within a SiO₂ film when spacer oxide films are subsequently formed on gate sidewalls. Accordingly, there occurs an “ONO penetration” phenomenon in which a thickness of the ONO film increases 15 to 30% higher than a deposition thickness.

Such an increase in the thickness of the ONO film may result in deviation depending upon the gate CD. Thus, if the gates of the memory cells do not have the same CD, the cells have an ONO film of a different thickness.

Further, the SiO₂ film has properties in which oxidization is more easily performed in a perpendicular direction than in a parallel direction. Thus, a thickness of the ONO film is not uniform even within the same cell. Accordingly, if the shapes of cells, such as cell height or cell width, are slightly differently defined, the cells have a different operating speed in a program/erase cycle, which leads to the slow program fail.

### SUMMARY OF THE INVENTION

Accordingly, the present invention has been made in view of the above problems, and it is an object of the present invention to provide a method of manufacturing flash memory devices, wherein an ONO penetration phenomenon can be prevented.

To achieve the above object, according to the present invention, there is provided a method of manufacturing a flash memory device, including the steps of forming a tunneling oxide film and a floating gate on a semiconductor substrate, sequentially stacking a first nitride film, a first oxide film, a second nitride film, a second oxide film and a third nitride film on the floating gate to form an inter-gate insulating film, and forming a control gate on the inter-gate insulating film.

The method preferably further includes the step of removing a native oxide film generated on the floating gate before the inter-gate insulating film is formed.

The first and third nitride films are preferably formed to a thickness of 10 to 15 Å.

The first oxide film is preferably formed by oxidizing a surface of the first nitride film.

The first oxide film is preferably formed by depositing an oxide film on the first nitride film by means of LPCVD method.

Preferably, a physical thickness of the inter-gate insulating film is set to be smaller than 180 Å, and an electrical thickness of the inter-gate insulating film is set to be smaller than 150 Å.

Preferably, a thickness of the second oxide film on the second nitride film is formed to be thicker than that of the first oxide film below the second nitride film.

The thickness of the first oxide film:the second nitride film:the second oxide film preferably has the ratio of 1:1:1.25 to 1:2:2.3.

Preferably, the first oxide film is formed to a thickness of 30 to 45 Å, the second nitride film is formed to a thickness of 40 to 60 Å, and the second oxide film is formed to a thickness of 50 to 70 Å.

### BRIEF DESCRIPTION OF THE DRAWINGS

FIGS. 1a and 1b are cross-sectional views for explaining a method of manufacturing a flash memory device according to an embodiment of the present invention.

### DETAILED DESCRIPTION OF PREFERRED EMBODIMENTS

Now, the preferred embodiments according to the present invention will be described with reference to the accompanying drawings. Since preferred embodiments are provided for the purpose that the ordinary skilled in the art are able to understand the present invention, they may be modified in various manners and the scope of the present invention is not limited by the preferred embodiments described later.

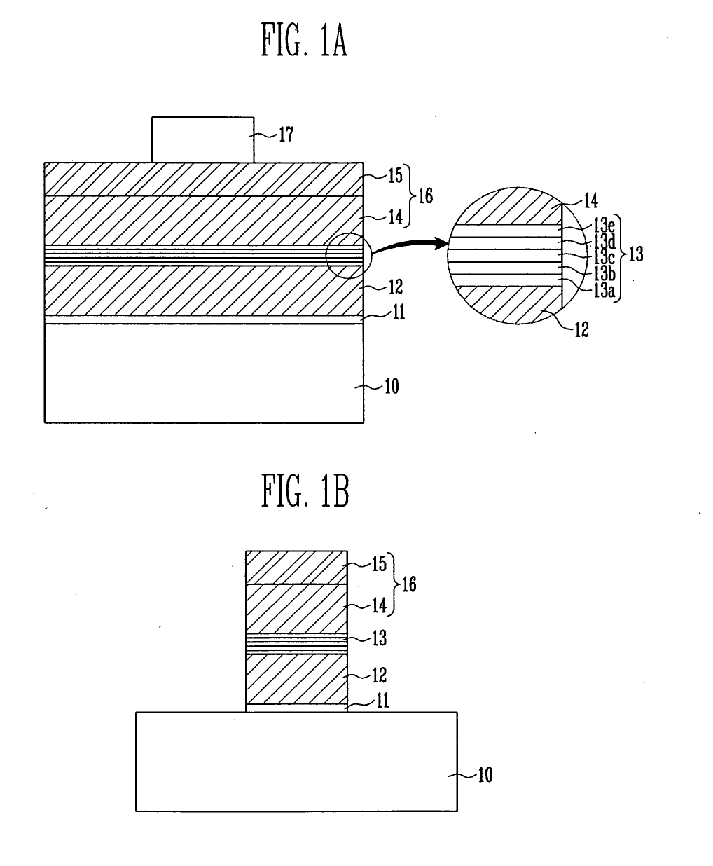

FIGS. 1a and 1b are cross-sectional views for explaining a method of manufacturing a flash memory device according to an embodiment of the present invention. FIG. 1 shows an example of the flash memory device having a stack type gate structure.

As shown in FIG. 1a, a tunneling oxide film 11 and a polysilicon film 12 for floating gate are sequentially formed on a semiconductor substrate 10.

A native oxide film, which is generated in the polysilicon film 12 for floating gate, is then removed by means of a pre-treatment cleaning process using a diluted HF and SC-1 solution. A first nitride film 13a, a first oxide film 13b, a second nitride film 13c, a second oxide film 13d and a third nitride film 13e are then sequentially stacked on the polysilicon film 12 for floating gate to form an inter-gate insulating film 13 of an NONON (Nitride-Oxide-Nitride-Oxide-Nitride) structure.

In this case, the first, second and third nitride films 13a, 13c and 13e are formed using a Si₃N₄ film, and the first and second oxide films 13b and 13d are formed using a SiO₂ film.

The first and third nitride films 13a and 13e serve to prevent a thickness of the inter-gate insulating film 13 from increasing although oxygen is penetrated in a subsequent oxidization process due to the removal of the interface of polysilicon and an oxide film. The first and third nitride films 13a and 13e are formed to have a final thickness of 10 to 15 Å.

Furthermore, the first oxide film 13b can be formed by means of LPCVD (Low Power Chemical Vapor Deposition) method, or can be formed by oxidizing some of the surface of the first nitride film 13a.

In the case where the first oxide film 13b is formed by LPCVD method, the first nitride film 13a can be formed to a thickness of 10 to 15 Å. In the event that the first oxide film 13b is formed by oxidizing some of the surface of the first nitride film 13a, the first nitride film 13a is thickly formed to a thickness of 30 to 60 Å, and the surface of the first nitride film 13a is then partially oxidized to form the first oxide film 13b. After the first oxide film 13b is formed, a thickness of the remaining first nitride film 13a is kept to 10 to 15 Å.

In this case, the second oxide film 13d is formed to a thickness thicker than that of the first oxide film 13b. A thickness of the first oxide film 13b, the second nitride film 13c and the second oxide film 13d is set to have the ratio of 1:1:1.25 to 1:2:2.3.

Preferably, the first oxide film 13b is formed to a thickness of 30 to 45 Å, the second nitride film 13c is formed to a thickness of 40 to 60 Å, and the second oxide film 13d is formed to a thickness of 50 to 70 Å.

Meanwhile, a physical thickness of the inter-gate insulating film 13 has to be smaller than 180 Å, and an electrical thickness thereof has to be smaller than 150 Å.

Furthermore, the process of forming the first nitride film 13a, the first oxide film 13b, the second nitride film 13c, the second oxide film 13d and the third nitride film 13e is controlled so that a time taken to form the inter-gate insulating film 13 is within 2 hours.

A polysilicon film 14 for control gate and a WSiₓ film 15 are then sequentially formed on the inter-gate insulating film 13.

The stack film of the polysilicon film 14 for control gate and the WSiₓ film 15 is used as a control gate 16.

Thereafter, a hard mask film 17 is formed on the WSiₓ film 15. As shown in FIG. 1b, the WSiₓ film 15, the polysilicon film 14 for control gate, the inter-gate insulating film 13, the polysilicon film 12 for floating gate, and the tunneling oxide film 11 are etched using the hard mask film 17 as a mask to form a gate of a stack structure.

Though not shown in the drawings, gate sidewall oxide films are formed on both sides of the structure from the tunneling oxide film 11 to the WSiₓ film 15.

As the polysilicon film 12 for floating gate, the polysilicon film 14 for control gate, and the inter-gate insulating film 13 sharing the interface are comprised of a nitride film component, the oxidization of the polysilicon film 12 for floating gate and the polysilicon film 14 for control gate are prevented upon formation of the gate sidewall oxide films. Thus, a thickness of the inter-gate insulating film 13 does not increase.

Fabrication of the flash memory device according to an embodiment of the present invention is thus completed.

In the above embodiment, the stack type structure has been described as an example. It is, however, to be understood that the present invention can be applied to gates of other types such as a self-aligned STI structure.

As described above, according to the present invention, an inter-gate insulating film is formed to have an NONON structure, thus removing the interface of polysilicon and an oxide film. It is thus possible to fundamentally prevent a thickness of an inter-gate insulating film from increasing due to a subsequent oxidization process.

Thus, the thickness of the inter-gate insulating film can be kept uniform regardless of the shape of a cell. Accordingly, there are advantages in that the operating speed among cells can be made uniform, and the slow program fail rate can be minimized.

Although the foregoing description has been made with reference to the preferred embodiments, it is to be understood that changes and modifications of the present invention may be made by the ordinary skilled in the art without departing from the spirit and scope of the present invention and appended claims.

1. A method of manufacturing a flash memory device, comprising the steps of:
forming a tunneling oxide film and a floating gate on a semiconductor substrate;
sequentially stacking a first nitride film, a first oxide film, a second nitride film, a second oxide film and a third nitride film on the floating gate to form an inter-gate insulating film; and
forming a control gate on the inter-gate insulating film,
wherein the first oxide film is formed by oxidizing a surface of the first nitride film.

2. The method as claimed in claim 1, further comprising the step of removing a native oxide film generated on the floating gate before forming the inter-gate insulating film.

3. The method as claimed in claim 1, wherein the first and third nitride films are formed to a thickness of 10 Å to 15 Å.

4. (canceled)

5. (canceled)

6. The method as claimed in claim 1, comprising setting a physical thickness of the inter-gate insulating film to be smaller than 180 Å, and setting an electrical thickness of the inter-gate insulating film to be smaller than 150 Å.

7. The method as claimed in claim 1, comprising forming a thickness of the second oxide film on the second nitride film to be thicker than that of the first oxide film below the second nitride film.

8. The method as claimed in claim 7, wherein the thickness of the first oxide film:the second nitride film:the second oxide film has the ratio of 1:1:1.25 to 1:2:2.3.

9. The method as claimed in claim 1, comprising forming the first oxide film to a thickness of 30 Å to 45 Å, forming the second nitride film to a thickness of 40 Å to 60 Å, and forming the second oxide film is to a thickness of 50 Å to 70 Å.
